(19) United States
(12) Patent Application Publication
(10) Pub. No.: US 2013/0306980 A1
(43) Pub. Date: Nov. 21, 2013

(54) NITRIDE SEMICONDUCTOR DEVICE AND MANUFACTURING METHOD THEREOF

(71) Applicant: ADVANCED POWER DEVICE RESEARCH ASSOCIATION, Yokohama-shi (JP)

(72) Inventors: Yuki NIIYAMA, Yokohama-shi (JP); Jiang LI, Yokohama-shi (JP); Sadahiro KATOU, Yokohama-shi (JP)

(73) Assignee: ADVANCED POWER DEVICE RESEARCH ASSOCIATION, Yokohama-shi (JP)

(21) Appl. No.: 13/952,652

(22) Filed: Jul. 28, 2013

Related U.S. Application Data
(63) Continuation of application No. PCT/JP2012/002114, filed on Mar. 27, 2012.

(30) Foreign Application Priority Data
Mar. 28, 2011 (JP) 2011-069810

(51) Int. Cl. H01L 29/778; H01L 29/66

(52) U.S. Cl. CPC H01L 29/778; H01L 29/66431
USPC 257/76; 257/194; 438/172

(57) ABSTRACT

A nitride semiconductor device includes a substrate, an electron transit layer and an electron supply layer that are sequentially formed above the substrate, where the electron supply layer has a different band gap energy than the electron transit layer, a drain electrode, a gate electrode, and a source electrode that is formed on the opposite side of the drain electrode with the gate electrode being sandwiched between the drain electrode and the source electrode. Here, a plurality of lower concentration regions are formed so as to be spaced away from each other on the surface of the electron transit layer between the gate electrode and the drain electrode. In the lower concentration regions, the concentration of a two-dimensional electron gas is lower than in other regions.

The contents of the following patent applications are incorporated herein by reference:
No. 2011-069810 filed in Japan on Mar. 28, 2011, and
No. PCT/JP2012/002114 filed on Mar. 27, 2012.

### BACKGROUND

1. Technical Field

The present invention relates to a nitride semiconductor device and a manufacturing method thereof.

2. Related Art

A normally-off MOSFET that exhibits both high mobility and high withstand voltage is conventionally known as a field-effect transistor using a nitride semiconductor, as disclosed in, for example, Japanese Patent Application Publication No. 2009-246292. This MOSFET achieves improved withstand voltage based on a two-step-shaped electron supply layer whose thickness is small in the region close to the gate electrode and large in the region close to the drain electrode.

Such a two-step-shaped electron supply layer may be formed by growing the electron supply layer in two separate phases or by subjecting the surface of the electron supply layer to dry etching. When the former technique is employed, crystal growth needs to be performed twice, which may result in lower productivity. When the latter technique is employed, on the other hand, a surface state occurs on the surface that has been subjected to the etching and electric current collapse increases the resistance. For these reasons, there were difficulties in realizing a nitride semiconductor device exhibiting a large electric current and a high withstand voltage by means of a simple manufacturing process.

### SUMMARY

A first aspect of the innovations may include a nitride semiconductor device including a substrate, an electron transit layer that is formed above the substrate, an electron supply layer that is formed on the electron transit layer, where the electron supply layer has a different band gap energy than the electron transit layer, a drain electrode that is formed on the electron supply layer, a gate electrode that controls an electric current flowing through the drain electrode, and a source electrode that is formed on an opposite side of the drain electrode with the gate electrode being positioned between the source electrode and the drain electrode. Here, a plurality of lower concentration regions are formed so as to be spaced away from each other on a surface of the electron transit layer between the gate electrode and the drain electrode, and in the plurality of lower concentration regions, a concentration of a two-dimensional electron gas is lower than in other regions.

A second aspect of the innovations may include a nitride semiconductor device including a substrate, an electron transit layer that is formed above the substrate, an electron supply layer that is formed on the electron transit layer, where the electron supply layer has a different band gap energy than the electron transit layer, and a cathode electrode and an anode electrode that are formed on the electron supply layer. Here, a plurality of lower concentration regions are formed so as to be spaced away from each other on a surface of the electron transit layer between the cathode electrode and the anode electrode, and in the plurality of lower concentration regions, a concentration of a two-dimensional electron gas is lower than in other regions.

A third aspect of the innovations may include a method of manufacturing a nitride semiconductor device, including forming an electron transit layer above a substrate, forming, on the electron transit layer, an electron supply layer that has a different band gap energy than the electron transit layer, forming a plurality of lower concentration regions so as to be spaced away from each other on a surface of the electron transit layer between a region in which a gate electrode is expected to be formed and a region in which a drain electrode is expected to be formed, where the plurality of lower concentration regions have a lower concentration of a two-dimensional electron gas than other regions, forming the drain electrode and the source electrode on the electron transit layer, and forming the gate electrode that controls an electric current flowing though the drain electrode.

A fourth aspect of the innovations may include a method of manufacturing a nitride semiconductor device, including forming an electron transit layer above a substrate, forming an electron supply layer on the electron transit layer, where the electron supply layer has a different band gap energy than the electron transit layer, forming a plurality of lower concentration regions so as to be spaced away from each other on a surface of the electron transit layer between a region in which a cathode electrode is expected to be formed and a region in which an anode electrode is expected to be formed, where the plurality of lower concentration regions have a lower concentration of a two-dimensional electron gas than other regions, forming the anode electrode on the electron supply layer, and forming the cathode electrode on the electron supply layer.

The summary clause does not necessarily describe all necessary features of the embodiments of the present invention. The present invention may also be a sub-combination of the features described above. The above and other features and advantages of the present invention will become more apparent from the following description of the embodiments taken in conjunction with the accompanying drawings.

### BRIEF DESCRIPTION OF THE DRAWINGS

FIG. 1 is a cross-sectional view illustrating a MOSFET relating to a first embodiment of a nitride semiconductor device according to the present invention.

FIG. 2 illustrates how the electric potential and field vary between the gate and the drain of a conventional MOSFET.

FIG. 3 illustrates how the electric potential and field vary between the gate and the drain of the MOSFET shown in FIG. 1.

FIG. 4 is a graph illustrating how the electric field varies between the gate and the drain of the MOSFET shown in FIG. 1.

FIG. 5 is a graph illustrating the relation between the electric field at the end of the drain electrode of the MOSFET shown in FIG. 1 and the doped amount of Si

FIG. 6 shows the first step of the method of manufacturing the MOSFET shown in FIG. 1.

FIG. 7 shows the step that is subsequent to the step shown in FIG. 6 and designed for forming a mask layer for ion implantation.

FIG. 8 shows the step that is subsequent to the step shown in FIG. 7 and designed for Si ion implantation.

FIG. 9 shows the step that is subsequent to the step shown in FIG. 8 and designed for annealing.

FIG. 10 shows the step that is subsequent to the step shown in FIG. 9 and designed for forming an opening that is adapted to serve as a recess.

FIG. 11 shows the step that is subsequent to the step shown in FIG. 10 and designed for forming the recess.

FIG. 12 shows the step that is subsequent to the step shown in FIG. 11 and designed for depositing a gate insulator.

FIG. 13 shows the step that is subsequent to the step shown in FIG. 12 and designed for forming a source electrode and a drain electrode.

FIG. 14 shows the step that is subsequent to the step shown in FIG. 13 and designed for forming a gate electrode.

FIG. 15 is a top view illustrating the MOSFET shown in FIG. 1.

FIG. 16 is a cross-sectional view illustrating a diode relating to a second embodiment of the nitride semiconductor device according to the present invention.

FIG. 17 shows the first step of the method of manufacturing the diode shown in FIG. 16.

FIG. 18 shows the step that is subsequent to the step shown in FIG. 17 and designed for forming a mask layer for ion implantation.

FIG. 19 shows the step that is subsequent to the step shown in FIG. 18 and designed for Si ion implantation.

FIG. 20 shows the step that is subsequent to the step shown in FIG. 19 and designed for annealing.

FIG. 21 shows the step that is subsequent to the step shown in FIG. 20 and designed for forming an anode electrode.

FIG. 22 shows the step that is subsequent to the step shown in FIG. 21 and designed for forming a cathode electrode.

FIG. 23 is a top view illustrating the diode shown in FIG. 16.

### DESCRIPTION OF EXEMPLARY EMBODIMENTS

Hereinafter, some embodiments of the present invention will be described. The embodiments do not limit the invention according to the claims, and all the combinations of the features described in the embodiments are not necessarily essential to means provided by aspects of the invention.

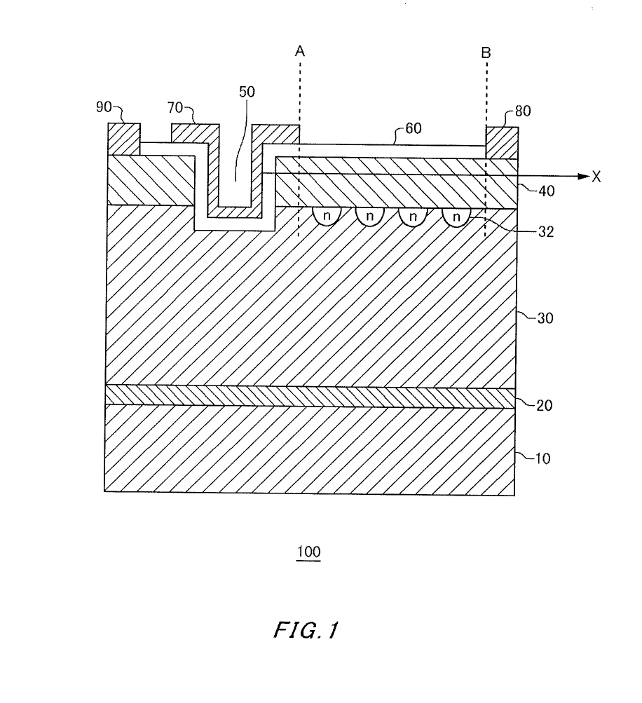

FIG. 1 is a cross-sectional view of a MOSFET 100 relating to a first embodiment of a nitride semiconductor device according to the present invention. Here, the nitride semiconductor device according to the present invention is not limited to a MOSFET. For example, the nitride semiconductor device may alternatively be a MISFET, a MESFET, or HFET.

The MOSFET 100 includes a substrate 10, a buffer layer 20, an electron transit layer 30, an electron supply layer 40, a gate insulator 60, a gate electrode 70, a drain electrode 80, and a source electrode 90. The substrate 10 may be made of Si, sapphire, SiC, or ZrB₂. The buffer layer 20 is interposed between the substrate 10 and the electron transit layer 30. The buffer layer 20 serves as a buffering layer adapted to have a lattice constant between the lattice constant of the substrate 10 and the lattice constant of the electron transit layer 30, and achieve lattice match between the substrate 10 and the electron transit layer 30 having different lattice constants, and reduce the dislocation density. The buffer layer 20 is, for example, formed by stacking six to ten GaN/AlN composite layers each of which is constituted by a GaN layer having a thickness of 200 nm and an MN layer having a thickness of 20 nm.

The electron transit layer 30 is interposed between the buffer layer 20 and the electron supply layer 40. The electron transit layer 30 generates a two-dimensional electron gas at the heterointerface between the electron transit layer 30 and the electron supply layer 40. The electron transit layer 30 may be, for example, a GaN layer doped with magnesium (Mg), which is a p-type dopant. The doped concentration of Mg may be 1E17 cm⁻³. Other than Mg, the p-type dopant may be Be, Zn, or C. The electron transit layer 30 may have a thickness of 1.5 μm to 2 μm, for example.

The electron supply layer 40 has a different band gap energy than the electron transit layer 30. The electron supply layer 40 contains AlₓGa₁₋ₓN (0.01≦x≦0.4). Since the GaN electron transit layer 30 and AlₓGa₁₋ₓN electron supply layer 40 have different lattice constants, lattice strain occurs and piezo polarization is generated. The piezo polarization generates an electric field, which forms a band offset at the heterointerface and thus produces a two-dimensional electron gas. The electron supply layer 40 has a thickness of 30 nm, for example.

The electron supply layer 40 may have a recess 50. The recess 50 may be a groove that has a rectangular bottom surface and penetrates through the electron supply layer 40 and reaches the electron transit layer 30. The recess 50 separates the electron supply layer 40 into the region on the side of the drain electrode 80 and the region on the side of the source electrode 90. The recess 50 may have a depth of approximately 60 nm and a width of approximately 2 μm.

The gate insulator 60 is formed so as to cover the surfaces of the electron transit layer 30 and the electron supply layer 40 that are exposed in the recess 50 and further cover the surface of the electron supply layer 40. The gate insulator 60 may be made of SiO₂. The gate insulator 60 may have a thickness of 10 nm, for example.

The gate electrode 70 is deposited on the gate insulator 60 and formed so as to penetrate through the electron supply layer 40. The gate electrode 70 penetrates through the electron supply layer 40 by being formed inside the recess 50. A portion of the gate electrode 70 may be formed on the surface of the electron supply layer 40. The gate electrode 70 may be made of polysilicon.

The drain electrode 80 and the source electrode 90 are formed on the electron supply layer 40 with the gate electrode 70 being positioned therebetween. The distance between the drain electrode 80 and the source electrode 90 is, for example, 30 μm. The drain electrode 80 and the source electrode 90 are made of, for example, Ti/Al. Note that, however, the material for the drain electrode 80 and the source electrode 90 is not limited to Ti/Al and may be any metal that can form ohmic contact with AlₓGa₁₋ₓN.

Between the gate electrode 70 and the drain electrode 80 on the surface of the electron transit layer 30, a plurality of lower concentration regions 32 are formed. Here, the term “lower concentration region” indicates a region in which the concentration of the two-dimensional electron gas is lower than in the other regions on the surface of the electron transit layer 30. The lower concentration regions 32 are spaced away from each other on the surface of the electron transit layer 30. Here, the lower concentration regions 32 may be arranged at even interval. For example, the lower concentration regions 32 may have a width of 2 μm and a depth of 20 nm and be arranged at intervals of 2 μm.

As an example, the lower concentration regions 32 are formed using ion implantation to introduce an n-type dopant to a predetermined concentration. The n-type dopant may be one of Si, Ge, and O. For example, if Si is introduced as the n-type dopant into the surface of the electron transit layer 30 using the ion implantation technique, n-type lower concentration regions 32 are formed at the heterointerface. In the lower concentration regions 32, the Si ion implantation lowers the band of the heterojunction interface. Therefore, the triangular potential well is reduced or eliminated, which may lower the concentration of the two-dimensional electron gas.

Since the lower concentration regions 32 are spaced away from each other on the surface of the p-type electron transit layer 30, successive pn junctions are formed along the direction in which the electrons transit. The pn junctions generate electric fields.

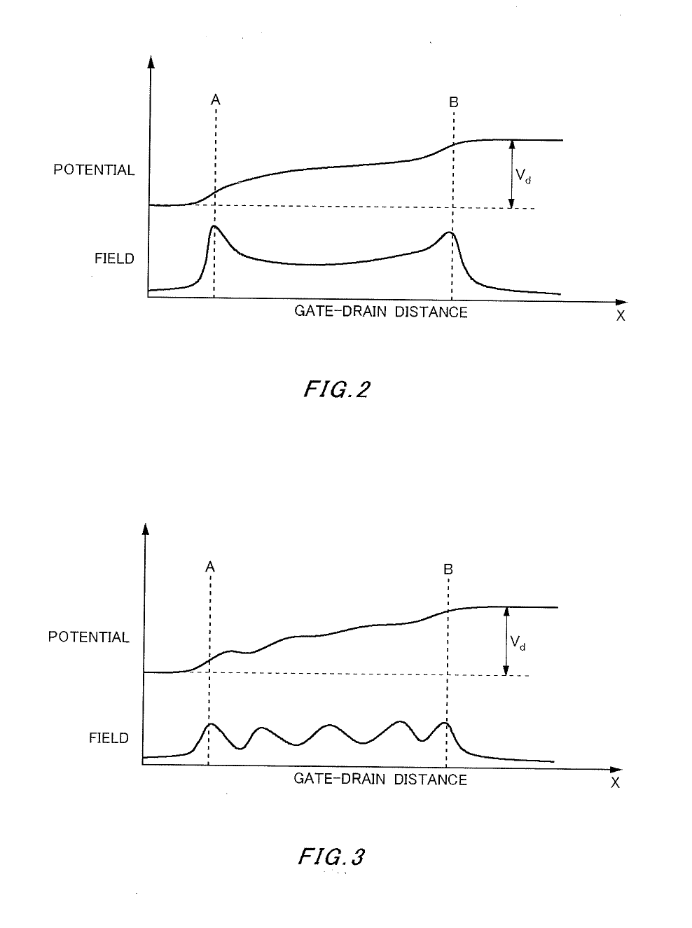

FIGS. 2 and 3 each show a graph representing how the electric potential and field in the electron supply layer 40 vary between the gate and the drain when the source electrode 90 and the gate electrode 70 of the MOSFET 100 are grounded and a drain voltage Vd is applied to the drain electrode 80. In the drawings, “A” denotes the end of the gate electrode 70 that is closer to the drain electrode 80, and “B” denotes the end of the drain electrode 80 that is closer to the gate electrode 70.

FIG. 2 is a graph showing how the electric potential and field vary between the gate electrode and the drain electrode when the lower concentration regions 32 are not provided. The electric potential increases more significantly at the positions denoted by “A” and “B” than in the other positions and gradually increases from the position “A” to the position “B.” On the other hand, the electric field has high peaks at the positions “A” and “B.” In other words, the electric field concentrates at the positions “A” and “B.” At the positions where the electric field concentrates, lower withstand voltage is observed.

FIG. 3 is a graph showing how the electric potential and field vary between the gate electrode and the drain electrode when the lower concentration regions 32 are provided. The electric potential gradually increases as the position moves from the gate electrode 70 to the drain electrode 80. The electric field has several low peaks between the position “A” and the position “B” but has no high peaks. In other words, the concentration of the electric field is reduced.

Here, the electric potential is calculated by integrating the electric field. Since the electric potential remains constant at the level Vd, the value calculated by integrating the electric field shown in FIG. 2 is equal to the value calculated by integrating the electric field shown in FIG. 3. In other words, the lower concentration regions 32 formed between the position “A” and the position “B” form pn junctions and thus generate electric field. This can achieve scattered electric field peaks. As a result, the concentration of the electric field can be reduced, and improved withstand voltage is thus achieved.

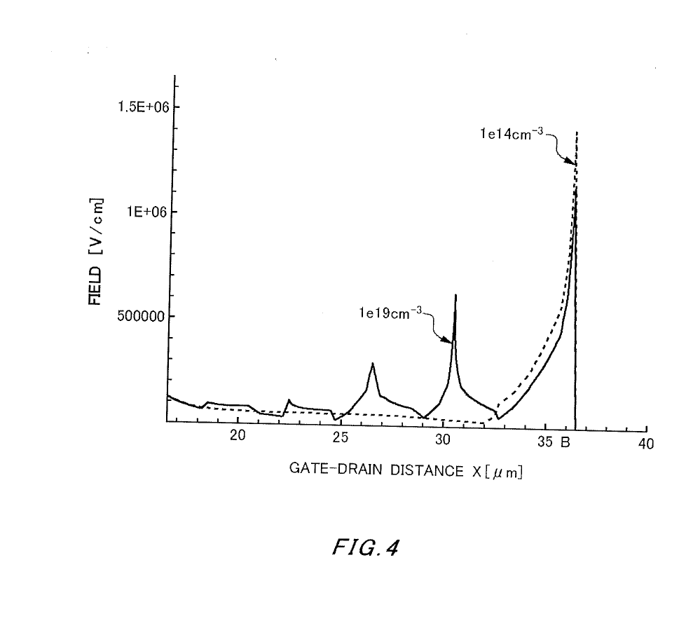

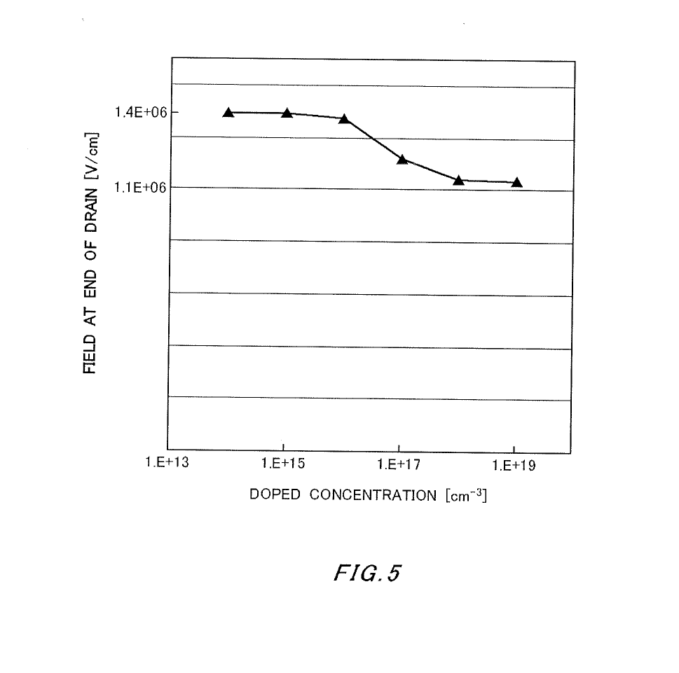

FIG. 4 is a graph illustrating how the electric field varies between the gate electrode and the drain electrode when the doped amount of Si is 1E14 cm⁻³ and 1E19 cm⁻³. In FIG. 4, the horizontal axis X represents the distance from the gate electrode. The position denoted by “B” in FIGS. 2 and 3 (the position of the end of the drain electrode 80) is in the vicinity of X=36 μm. When the doped amount of Si is 1E14 cm⁻³, the electric field shows an acute peak only at the position “B”, and the peak value is approximately 1.4E+06 (V/cm).

In other words, the electric field concentrates at the end of the drain electrode 80. This indicates that, when the doped amount is 1E14 cm⁻³, even the lower concentration regions 32 formed by the Si ion implantation do not effectively reduce the concentration of the electric field.

When the doped amount of Si is 1E19 cm⁻³, on the other hand, the electric field has an acute peak at the position “B” but the peak value is as low as approximately 1.1E+06 (V/cm). Furthermore, the electric field has a plurality of low peaks at positions other than the position “B.” In other words, the concentration of the electric field is reduced at the end of the drain electrode 80. Accordingly, when the doped amount is 1E19 cm⁻³, the lower concentration regions 32 formed by the Si ion implantation can effectively reduce the concentration of the electric field.

FIG. 5 is a graph illustrating the relation between the electric field at the end of the drain electrode 80 and the doped concentration of Si. The graph shown in FIG. 5 can indicate that, as the doped concentration of Si reaches 1E+16 cm⁻³ or higher, the electric field at the end of the drain electrode 80 starts to decrease. Stated differently, once the doped amount reaches 1 E+16 cm⁻³ or higher, the electric field starts to peak at a position other than the end of the drain electrode 80. Therefore, the doped concentration of Si is preferably 1E+16 cm⁻³ or hither to effectively reduce the concentration of the electric field.

If the doped concentrations of Si reaches 1E+17 cm⁻³ or higher, the electric field at the end of the drain electrode 80 significantly drops. Accordingly, the doped concentration of Si may be 1E+17 cm⁻³ or higher. When the doped concentration of Si is 1E+18 cm⁻³ or higher, the electric field at the end of the drain electrode 80 does not vary much even if the doped concentration increases any further. Therefore, the doped concentration of Si may be 1E+18 cm⁻³ or higher.

The predetermined concentration of the n-type dopant that is introduced by ion implantation may be constant among the lower concentration regions 32. Alternatively, the predetermined concentration of the n-type dopant that is introduced by ion implantation may be higher in the lower concentration regions 32 that are closer to the drain electrode 80 than in the lower concentration regions 32 that are closer to the gate electrode 70. In this way, the depletion layer is facilitated to grow both in the region that is closer to the gate electrode 70 and in the region that is closer to the drain electrode 80. Accordingly, the withstand voltage is improved.

The lower concentration regions 32 may be formed by applying laser to the surface of the electron transit layer 30. The laser is, for example, ultraviolet laser. As discussed later, the lower concentration regions 32 may be formed by scanning ultraviolet laser having predetermined wavelength and power over openings 44 in a mask layer 41 or by selectively applying such ultraviolet laser over the openings 44. Here, the predetermined wavelength is longer than the fundamental absorption edge of AlGaN and shorter than the fundamental absorption edge of GaN. In addition, the predetermined power indicates power to cause crystal defects at the positions corresponding to the openings 44 on the surfaces of the electron transit layer 30 and the electron supply layer 40. The crystal defects form a surface state that catches the electrons of the two dimensional electron gas. Accordingly, the concentration of the two-dimensional electron gas is decreased.

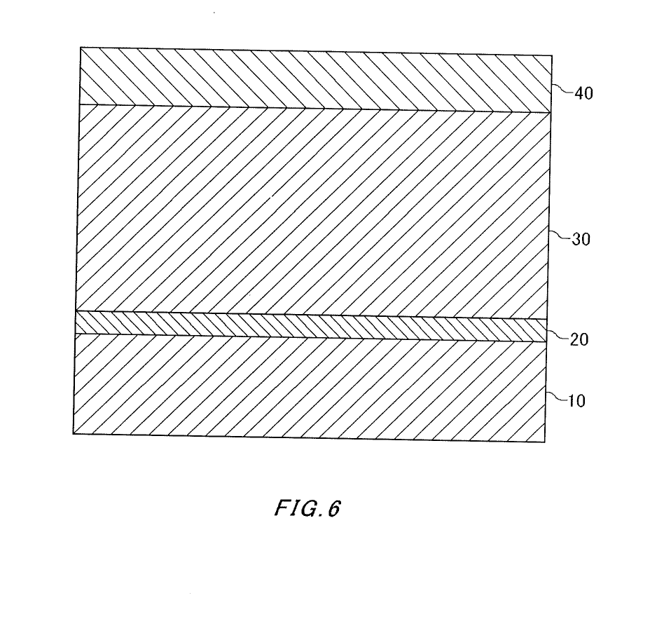

FIGS. 6 to 14 show the steps of the method of manufacturing the MOSFET 100. The method of manufacturing the MOSFET 100 includes the step of sequentially forming the buffer layer 20, the electron transit layer 30, and the electron supply layer 40 on the semiconductor substrate 10, the step of isolating the individual devices, the step of forming the lower concentration regions 32, the step of forming the recess 50, the step of depositing the gate insulator 60, the step of forming the drain electrode 80 and the source electrode 90 on the electron supply layer 40, and the step of forming the gate electrode 70. The following description assumes that a semiconductor layer is formed by epitaxial growth using, for example, metal organic chemical vapor deposition (MOCVD), halide vapor phase epitaxy (HYPE), or molecular beam epitaxy (MBE).

FIG. 6 shows the first step of the method of manufacturing the MOSFET 100. For example, the buffer layer 20, which is formed by, for example, stacking six to ten GaN/AlN composite layers, is grown on the semiconductor substrate 10 that is made of Si and whose main surface is the (111) plane. Subsequently, for example, the electron transit layer 30 is formed by growing p-type GaN to a thickness of approximately 1.5 μm on the buffer layer 20 using, as the dopant, Mg having a controlled concentration of 1E17 cm⁻³. After this, for example, the electron supply layer 40 that is made of AlGaN and has the Al ratio of 0.2 is grown to a thickness of approximately 30 nm on the electron transit layer 30. When the electron supply layer 40 is grown, AlGaN may be doped with Si of approximately 1E17 cm⁻³ using a silane gas.

Following this, the step of isolating the individual devices is performed. A photoresist is applied to the surface of the electron supply layer 40, and photolithography is performed on the photoresist to form a device isolating pattern. After this, a groove having a depth of approximately 200 nm is formed from the surface of the electron supply layer 40 towards the electron transit layer 30 by dry etching such as ICP and RIE. After this, the photoresist is removed using acetone to completely isolate the individual devices. FIG. 6 shows the region of one of the devices obtained by the device isolation.

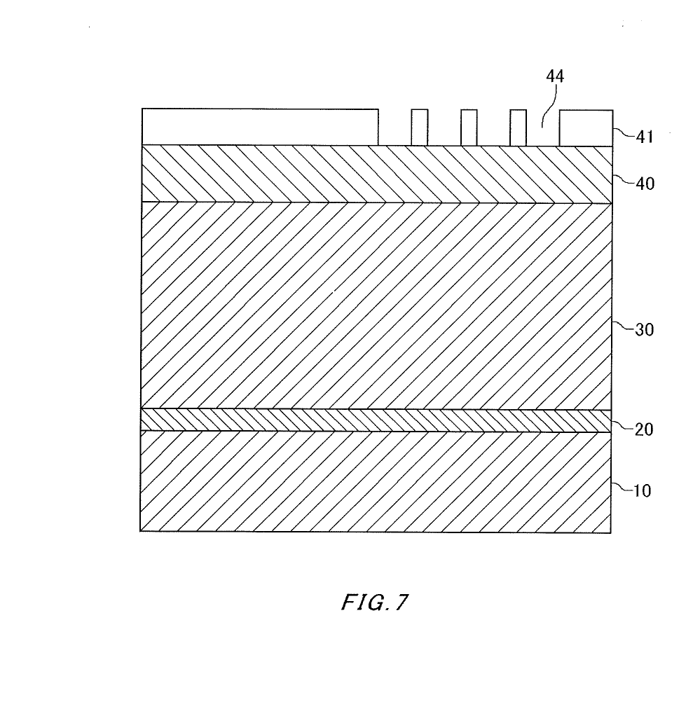

FIG. 7 shows the step that is subsequent to the step shown in FIG. 6. Using plasma CVD, the mask layer 41 that is, for example, made of SiO₂ and has a thickness of approximately 1 μm is deposited on the entire surface of the electron supply layer 40. Following this, using photolithography, the openings 44 are formed in the regions in which the lower concentration region 32 are expected to be formed, between the region in which the gate electrode 70 is expected to be formed and the region in which the drain electrode 80 is expected to be formed. Here, the openings 44 may be arranged at even intervals.

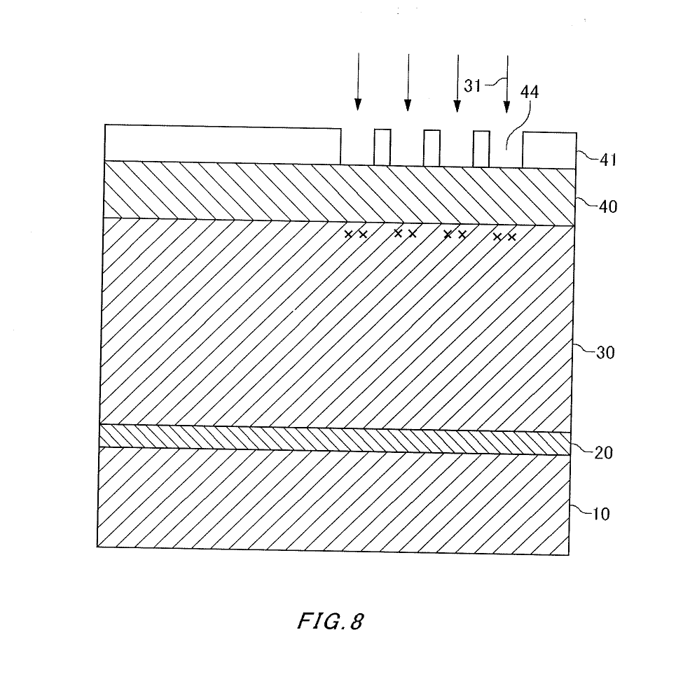

FIG. 8 shows the step that is subsequent to the step shown in FIG. 7. The step of forming the lower concentration regions 32 includes a step of introducing an n-type dopant to a predetermined concentration using ion implantation. The n-type dopant may be one of Si, Ge and O. Using ion implantation, Si ions 31 are injected into the openings 44 of the mask layer 41, for example, with the doped amount being set to approximately 1E16 cm⁻³ to 1E19 cm⁻³ and the acceleration voltage being set to 10 keV to 30 keV. The acceleration voltage is set in such a manner that the Si ions 31 are injected into the surface of the electron transit layer 30.

The ion implantation may be completed in a single cycle or divided into a plurality of cycles. When the ion implantation is divided into a plurality of cycles, Si ions may be injected to a lower concentration, for example, with the doped amount being set to, for example, approximately 1E16 cm⁻³ into the openings 44 that are closer to the region in which the gate electrode 70 is expected to be formed, and Si ions may be injected to a higher concentration, for example, with the doped amount being set to, for example, approximately 1E19 cm⁻³ into the openings 44 that are closer to the region in which the drain electrode 80 is expected to be formed.

The step of forming the lower concentration regions 32 includes a step of forming crystal defects by applying laser. The ion implantation may be replaced with ultraviolet laser application towards the openings 44 in the mask layer 41. In this case, the mask layer 41 may be made of a metal. As discussed above, the lower concentration regions 32 may be formed by scanning the ultraviolet laser having the predetermined wavelength and power over the openings 44 in the mask layer 41 or selectively applying such ultraviolet laser to the openings 44. The radiation is not limited to the ultraviolet laser and may be any radiation that can form crystal defects on the surface of the electron transit layer 30.

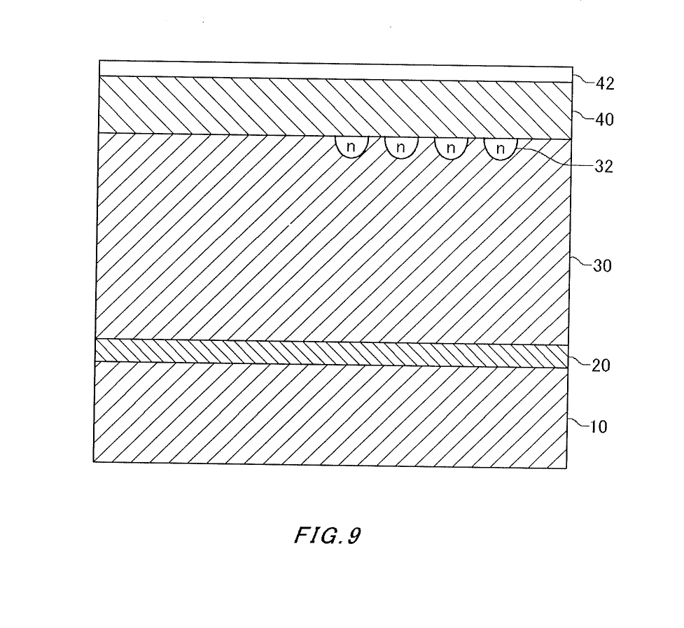

FIG. 9 shows the step that is subsequent to the step shown in FIG. 8. After the completion of the ion implantation, the mask layer 41 is removed using hydrofluoric acid. Following this, using plasma CVD, a SiO₂ film 42 is deposited to a thickness of 500 nm, for example, over the entire surface of the electron supply layer 40. After this, using Rapid Thermal Anneal (RTA), activation annealing is performed, for example, for a duration of ten seconds at a temperature of 1200° C. The activation annealing activates the Si ions that have been injected into the surface of the electron transit layer 30 to form the lower concentration regions 32 in which the concentration of the two-dimensional electron gas is lower than in the other regions and that are spaced away from each other.

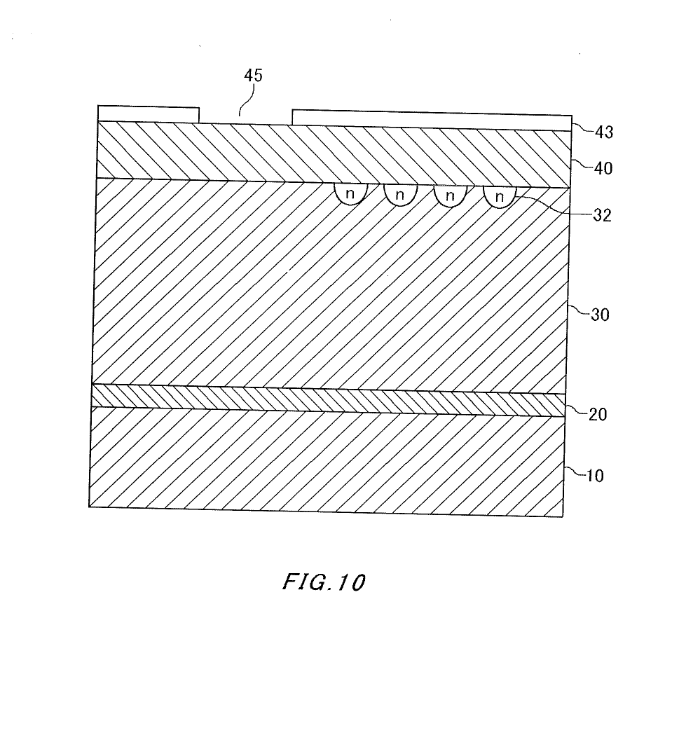

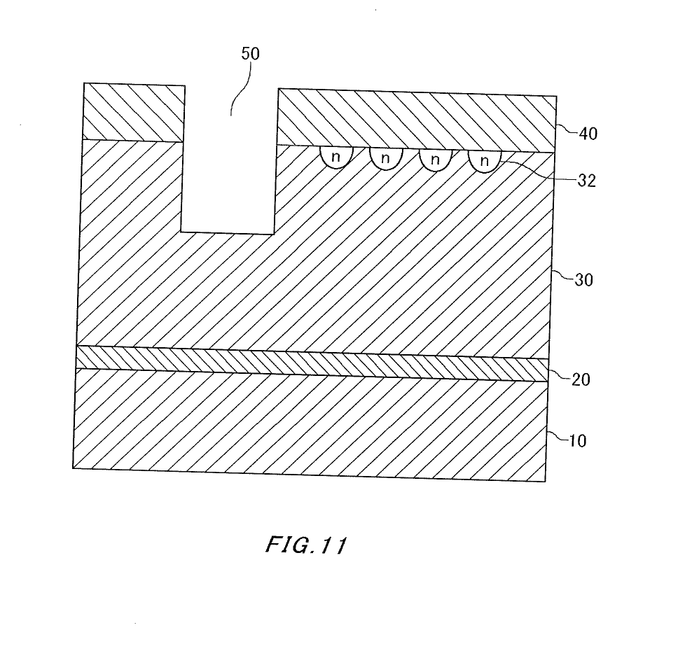

FIG. 10 shows the step that is subsequent to the step shown in FIG. 9. The SiO₂ film 42 is removed by hydrofluoric acid. After this, using plasma CVD, a mask layer 43 that is made of SiO₂ and has a thickness of approximately 300 nm is deposited on the electron supply layer 40. Subsequently, using photolithography, patterning is performed to form an opening 45 using a hydrofluoric acid aqueous solution in the region in which the recess 50 is expected to be formed.

FIG. 11 shows the step that is subsequent to the step shown in FIG. 10. After the opening 45 is formed, dry etching such as RIE is used to etch the electron supply layer 40 and the electron transit layer 30 under the opening 45 to a depth of approximately 60 nm, so that the recess 50 is formed. The electron supply layer 40 is divided into two regions by the recess 50. In addition, a portion of the surface of the electron transit layer 30 is drilled when the recess 50 is formed. After this, the mask layer 43 is removed using a hydrofluoric acid aqueous solution.

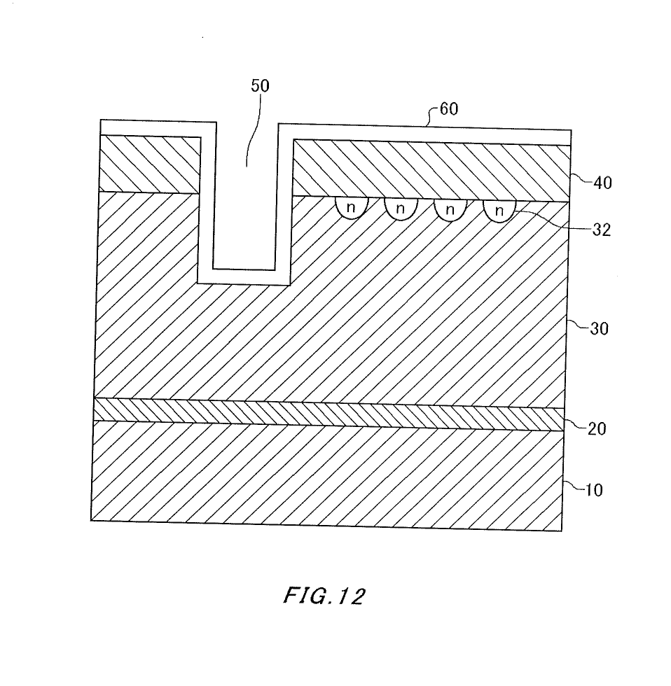

FIG. 12 shows the step that is subsequent to the step shown in FIG. 11. Using plasma CVD, the gate insulator 60 that is made of SiO₂ and has a thickness of approximately 60 nm is formed so as to cover the entire surface of the electron supply layer 40 and the entire inner surface of the recess 50.

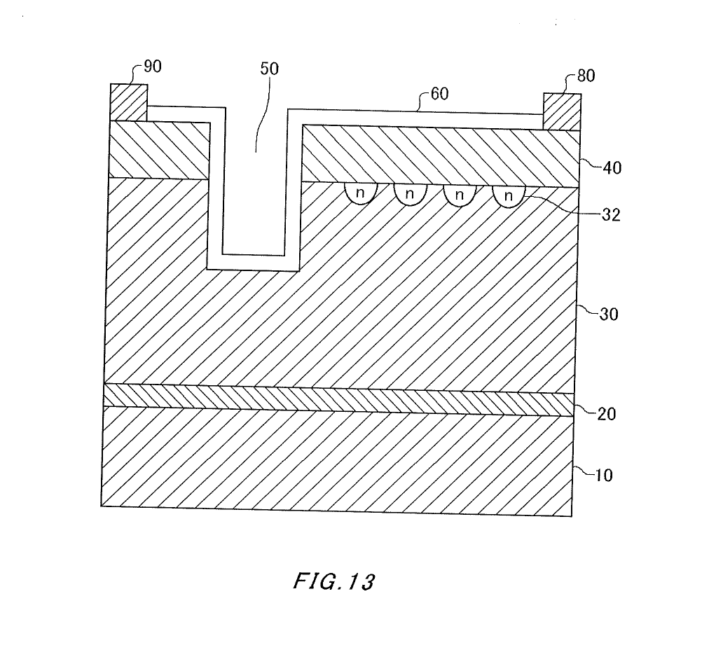

FIG. 13 shows the step that is subsequent to the step shown in FIG. 12. Using photolithography, openings are formed in the regions in the gate insulator 60 in which the drain electrode 80 and the source electrode 90 are expected to be formed. After this, using the lift-off method, the drain electrode 80 and the source electrode 90 are formed on the electron supply layer 40 that is exposed through the openings. The drain electrode 80 and the source electrode 90 form ohmic contact with the electron supply layer 40, and have a Ti/Al structure having thicknesses of 25 nm/300 nm, for example. The material for the drain electrode 80 and the source electrode 90 is not limited to Ti/Al and may be any material that can form ohmic contact with the electron supply layer 40.

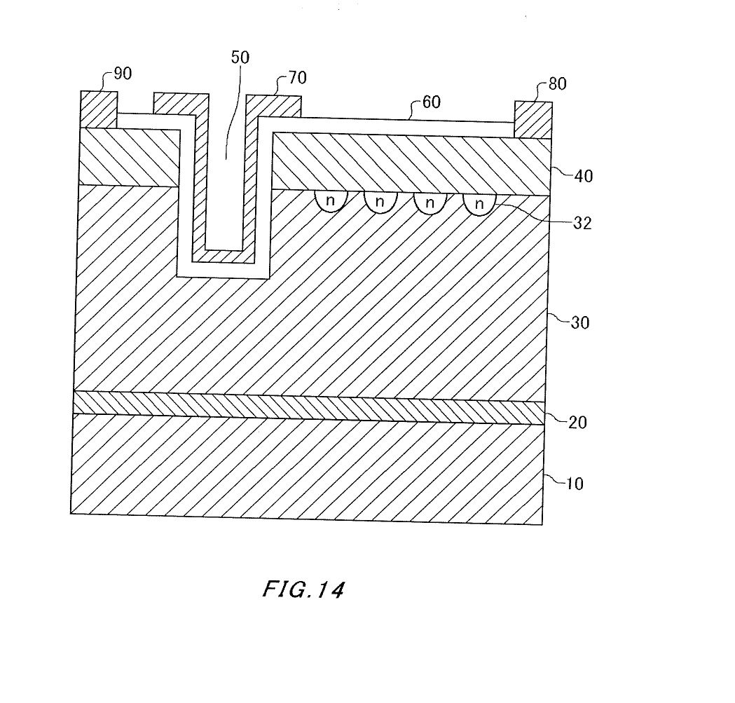

FIG. 14 shows the step that is subsequent to the step shown in FIG. 13. Using low pressure chemical vapor deposition (LPCVD) or sputtering, polysilicon is deposited on the entire surface of the device. After this, thermal diffusion is performed for a duration of 20 minutes at a temperature of 900° C. using a thermal diffusion furnace in which a POCl₃ gas is enclosed. The thermal diffusion dopes the polysilicon with phosphorous (P). Alternatively, the polysilicon may be doped with P by performing thermal diffusion after P is deposited on the polysilicon.

After this, the polysilicon is removed by photolithography in such a manner that the polysilicon is left between the drain electrode 80 and the source electrode 90. In this manner, the gate electrode 70 is formed. The material for the gate electrode 70 is not limited to polysilicon and may alternatively be Au, Pt, Ni and the like, in which case the gate electrode 70 may be formed using the lift-off method.

By performing the above-described steps, the MOSFET 100 shown in FIG. 1 is manufactured. When manufactured in the above-described manner, the MOSFET 100 can be fabricated using a simple process and can realize a normally-off nitride semiconductor device exhibiting a high withstand voltage and a large electric current since the lower concentration regions 32 can be formed by performing Si ion implantation only once.

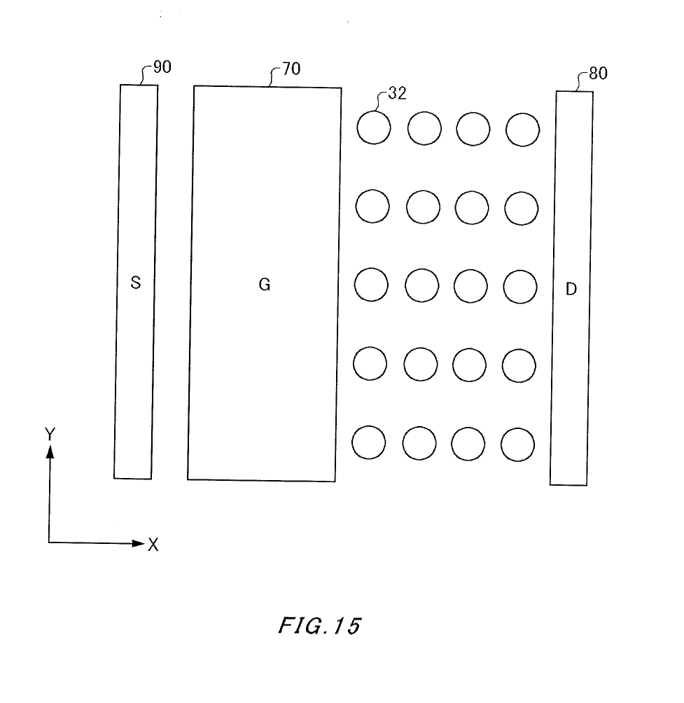

FIG. 15 is a top view illustrating the MOSFET 100. The lower concentration regions 32 are arranged at even intervals and in a matrix on the surface of the electron transit layer 30. In other words, the lower concentration regions 32 may be arranged at even intervals in the X axis direction and at even intervals in the Y axis direction on the surface of the electron transit layer 30. If the lower concentration regions 32 are arranged in the above-described manner, a large number of pn junctions can be formed in the region between the gate electrode 70 and the drain electrode 80. Therefore, the concentration of the electrical field can be more reduced. Accordingly, the MOSFET 100 can achieve high mobility and improved withstand voltage.

Alternatively, the lower concentration regions 32 may be arranged at different intervals between in the X axis direction and in the Y axis direction. For example, the lower concentration regions 32 that are adjacent to each other in the Y axis direction may be out of alignment in the X axis direction and differently positioned in the X axis direction by half the interval at which the lower concentration regions 32 are arranged in the X axis direction. In this case, the interval between the lower concentration regions 32 in the Y axis direction is twice as large as the interval between the lower concentration regions 32 in the X axis direction. When the lower concentration regions 32 are arranged in this manner, the concentration of the electric field can be also reduced.

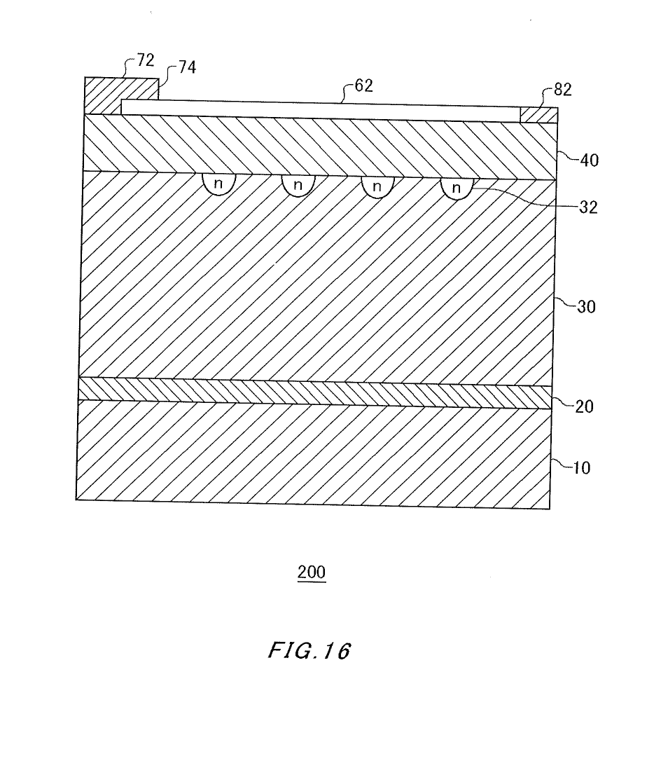

FIG. 16 is a cross-sectional view illustrating a diode 200 relating to a second embodiment of the nitride semiconductor device according to the present invention. The diode 200 include the substrate 10, the buffer layer 20, the electron transit layer 30, the electron supply layer 40, a passivation film 62, a cathode electrode 72, an anode electrode 82, and a field plate 74. The substrate 10, the buffer layer 20, the electron transit layer 30 and the electron supply layer 40 are the same as in the first embodiment and not explained here.

The passivation film 62 electrically separates the cathode electrode 72 and the anode electrode 82 from each other and serves as a surface protection film to protect the device from external environment. The passivation film 62 is made of SiO₂ and has a thickness of 300 nm, for example. Other than SiO₂, the passivation film 62 may be alternatively made of PSG or Si₃N₄.

The cathode electrode 72 and the anode electrode 82 are formed on the electron supply layer 40 with a distance of approximately 30 μm being provided therebetween, for example. The cathode electrode 72 forms a Schottky contact with the electron supply layer 40. The cathode electrode is, for example, a Schottly electrode made of Ni/Au. The material for the cathode electrode is not limited to Ni/Au and may be any metal that can form a Schottky contact with the electron supply layer 40.

On the cathode electrode 72, the field plate 74 is formed that is capable of extending in the direction toward the anode electrode 82. The field plate 74 can serve to reduce electric current collapse. The anode electrode 82 forms an ohmic contact with the electron supply layer 40. The anode electrode 82 is made of, for example, Ti/Al. The material for the anode electrode 82 is not limited to Ti/Al and may be any metal that can form an ohmic contact with the electron supply layer 40.

Between the cathode electrode 72 and the anode electrode 82, the lower concentration regions 32 are formed on the surface of the electron transit layer 30. Here, the term “lower concentration region” means a region in which the concentration of the two-dimensional electron gas is lower than in the other regions on the surface of the electron transit layer 30. The lower concentration regions 32 are spaced away from each other on the surface of the electron transit layer 30.

The lower concentration regions 32 have the same configuration and produce the same effect as in the first embodiment, and their configuration and effects are thus not explained here. The lower concentration regions 32 effectively reduce the concentration of the electrical field and contribute to improve the withstand voltage.

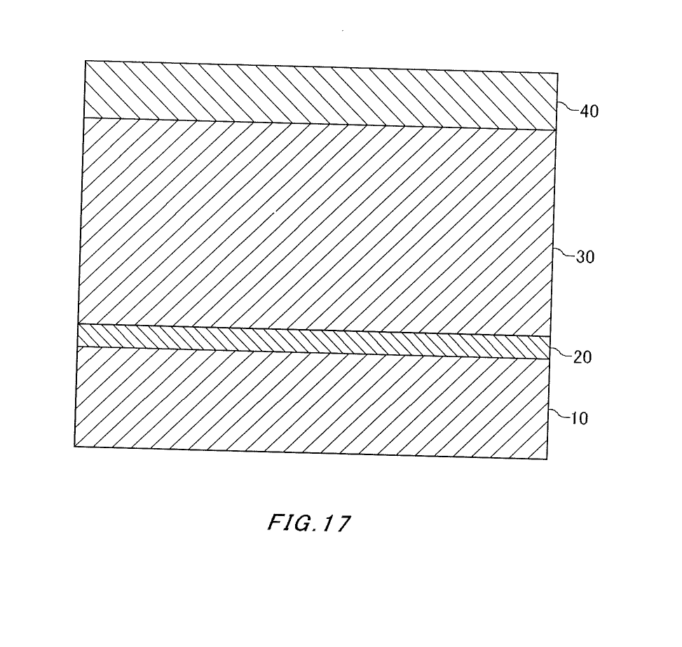

FIGS. 17 to 21 illustrate the steps of the method of manufacturing the diode 200. The method of manufacturing the diode 200 includes the step of sequentially forming the buffer layer 20, the electron transit layer 30, and the electron supply layer 40 on the substrate 10, the step of isolating the individual devices, the step of forming the lower concentration regions 32, the step of forming the passivation film 62, the step of forming the anode electrode 82 on the electron supply layer 40, the step of forming the cathode electrode 72 on the electron supply layer 40, and the step of forming the field plate 74 on the cathode electrode 72.

FIG. 17 shows the first step of the method of manufacturing the diode 200. For example, the buffer layer 20, which is formed by, for example, stacking six to ten GaN/AlN composite layers, is grown on the semiconductor substrate 10 that is made of Si and whose main surface is the (111) plane. Subsequently, for example, the electron transit layer 30 is formed by growing p-type GaN to a thickness of approximately 1.5 μm on the buffer layer 20 using, as the dopant, Mg having a controlled concentration of 1E17 cm⁻³. After this, for example, the electron supply layer 40 that is made of AlGaN and has the Al ratio of 0.2 is grown to a thickness of approximately 30 nm on the electron transit layer 30. When the electron supply layer 40 is grown, AlGaN may be doped with Si of approximately 1E17 cm⁻³ using a silane gas.

Following this, the step of isolating the individual devices is performed. A photoresist is applied to the surface of the electron supply layer 40, and photolithography is performed on the photoresist to form a device isolating pattern. After this, a groove having a depth of approximately 200 nm is formed from the surface of the electron supply layer 40 towards the electron transit layer 30 by dry etching such as ICP and RIE. After this, the photoresist is removed using acetone to completely isolate the individual devices. FIG. 17 shows the region of one of the devices obtained by the device isolation.

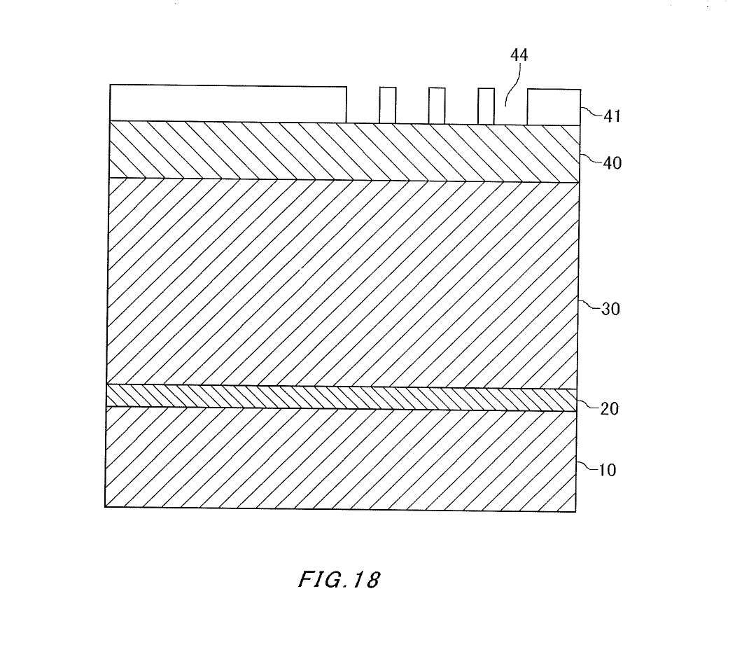

FIG. 18 shows the step that is subsequent to the step shown in FIG. 17. Using plasma CVD, the mask layer 41 that is, for example, made of SiO₂ and has a thickness of approximately 1 μm is deposited on the entire surface of the electron supply layer 40. Following this, using photolithography, the openings 44 are formed in the regions in which the lower concentration regions 32 are expected to be formed, between the region in which the cathode electrode 72 is expected to be formed and the region in which the anode electrode 82 is expected to be formed. Here, the openings 44 may be arranged at even intervals.

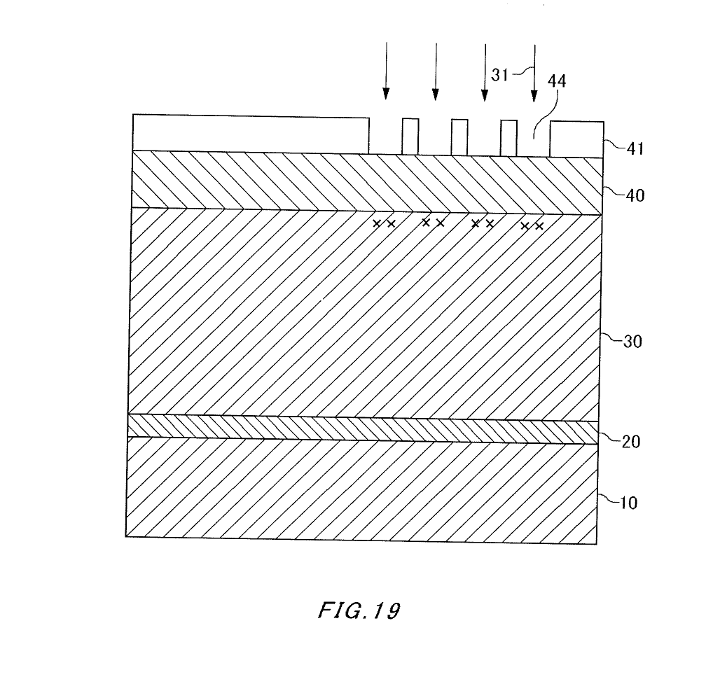

FIG. 19 shows the step that is subsequent to the step shown in FIG. 18. The step of forming the lower concentration regions 32 includes a step of introducing an n-type dopant to a predetermined concentration using ion implantation. The n-type dopant may be one of Si, Ge and O. Using ion implantation, the Si ions 31 are injected into the openings 44 of the mask layer 41, for example, with the doped amount being set to approximately 1E16 cm⁻³ to 1E19 cm⁻³ and the acceleration voltage being set to 10 keV to 30 keV. The acceleration voltage is set in such a manner that the Si ions 31 are injected into the surface of the electron transit layer 30.

The ion implantation may be completed in a single cycle or divided into a plurality of cycles. When the ion implantation is divided into a plurality of cycles, Si ions may be injected to a lower concentration, for example, with the doped amount being set to, for example, approximately 1E16 cm⁻³ into the openings 44 that are closer to the region in which the anode electrode 82 is expected to be formed, and Si ions may be injected to a higher concentration, for example, with the doped amount being set to, for example, approximately 1E19 cm⁻³ into the openings 44 that are closer to the region in which the cathode electrode 72 is expected to be formed.

The step of forming the lower concentration regions 32 includes a step of forming crystal defects by applying laser. The ion implantation may be replaced with ultraviolet laser application towards the openings 44 in the mask layer 41. In this case, the mask layer 41 may be made of a metal. The lower concentration regions 32 may be formed by scanning ultraviolet laser having predetermined wavelength and power over the openings 44 in the mask layer 41 or by selectively applying such ultraviolet laser over the openings 44. Here, the predetermined wavelength is longer than the fundamental absorption edge of AlGaN and shorter than the fundamental absorption edge of GaN. In addition, the predetermined power indicates power to cause crystal defects at the positions corresponding to the openings 44 on the surfaces of the electron transit layer 30 and the electron supply layer 40. The radiation is not limited to the ultraviolet laser and may be any radiation that can form crystal defects on the surface of the electron transit layer 30.

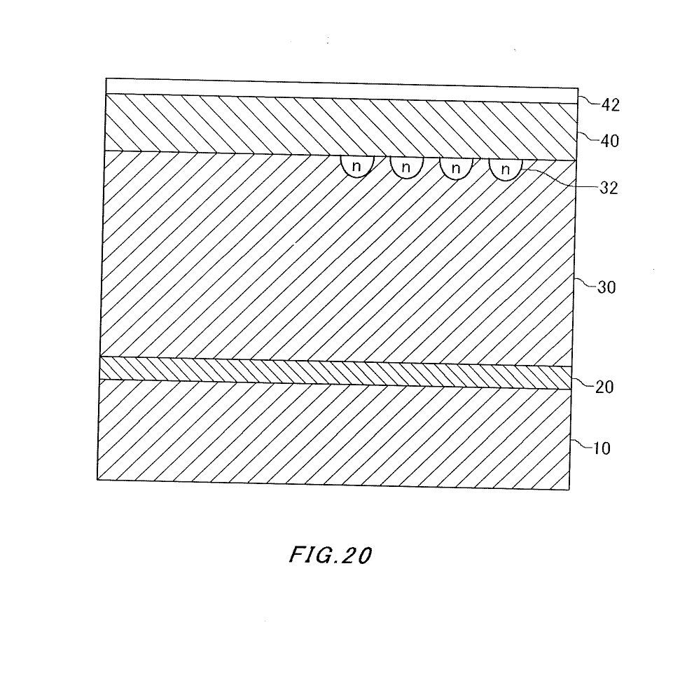

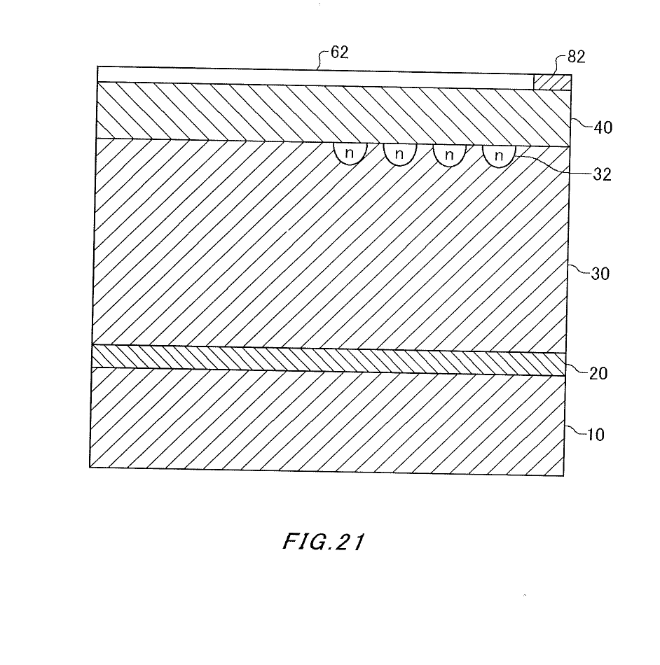

FIG. 20 shows the step that is subsequent to the step shown in FIG. 19. After the completion of the ion implantation, the mask layer 41 is removed using hydrofluoric acid. Following this, using plasma CVD, the SiO₂ film 42 is deposited to a thickness of 500 nm, for example, over the entire surface of the electron supply layer 40. After this, using Rapid Thermal Anneal (RTA), activation annealing is performed, for example, for a duration of ten seconds at a temperature of 1200° C. The activation annealing activates the Si ions that have been injected into the surface of the electron transit layer 30 to form the lower concentration regions 32 in which the concentration of the two-dimensional electron gas is lower than in the other regions and that are spaced away from each other.

FIG. 21 shows the step that is subsequent to the step shown in FIG. 20. The SiO₂ film 42 is removed by hydrofluoric acid. After this, using plasma CVD, the passivation film 62 that is made of SiO₂ and has a thickness of approximately 300 nm is deposited on the entire surface of the electron supply layer 40. Other than SiO₂, the passivation film may be formed by depositing Si₃N₄ or PSG using thermal CVD.

After this, using photolithography, an opening is formed in the region in which the anode electrode 82 is expected to be formed. Subsequently, using the lift-off method, the anode electrode 82 is formed on a portion of the electron supply layer 40 that is exposed through the opening. The anode electrode 82 is designed to form an ohmic contact with the electron supply layer 40 and has a Ti/Al structure having thicknesses of 25 nm/300 nm, for example.

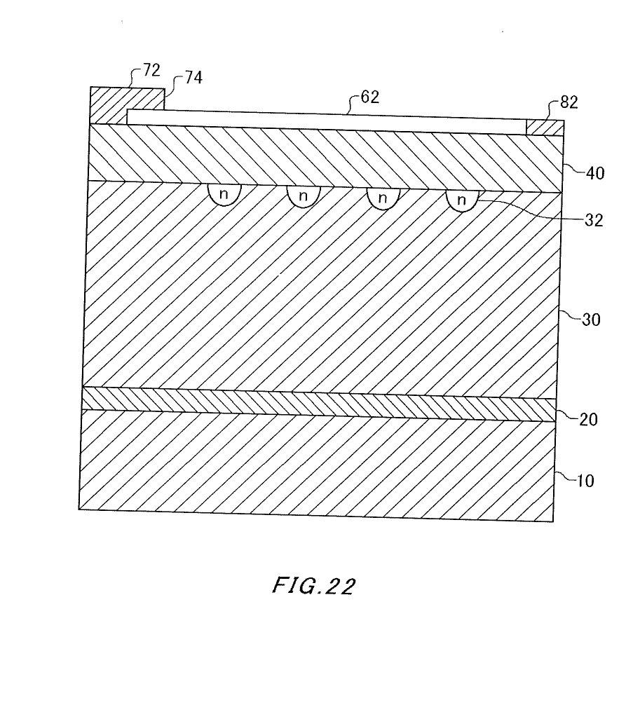

FIG. 22 shows the step that is subsequent to the step shown in FIG. 21. Using photolithography, an opening is formed in the region in which the cathode electrode 72 is expected to be formed. Subsequently, using the lift-off method, the cathode electrode 72 is formed in a portion of the electron supply layer 40 that is exposed through the opening. The cathode electrode 72 is designed to form a Schottky contact with the electron supply layer 40, and has a Ni/Au structure having thicknesses of 25 nm/25 nm, for example.

Subsequently, using photolithography, an opening is formed in the region in which the field plate 74 is expected to be formed. After this, using the lift-off method, the field plate 74 is formed on portions of the cathode electrode 72 and the electron supply layer 40 that are exposed through the opening. The field plate 74 is capable of extending in the direction from the cathode electrode 72 to the anode electrode 82.

By performing the above-described steps, the diode 200 shown in FIG. 16 can be manufactured. When manufactured in the above-described manner, the diode 200 can be fabricated using a simply process and can realize a nitride semiconductor device exhibiting a high withstand voltage and a large electric current since the lower concentration regions 32 can be formed by performing Si ion implantation once.

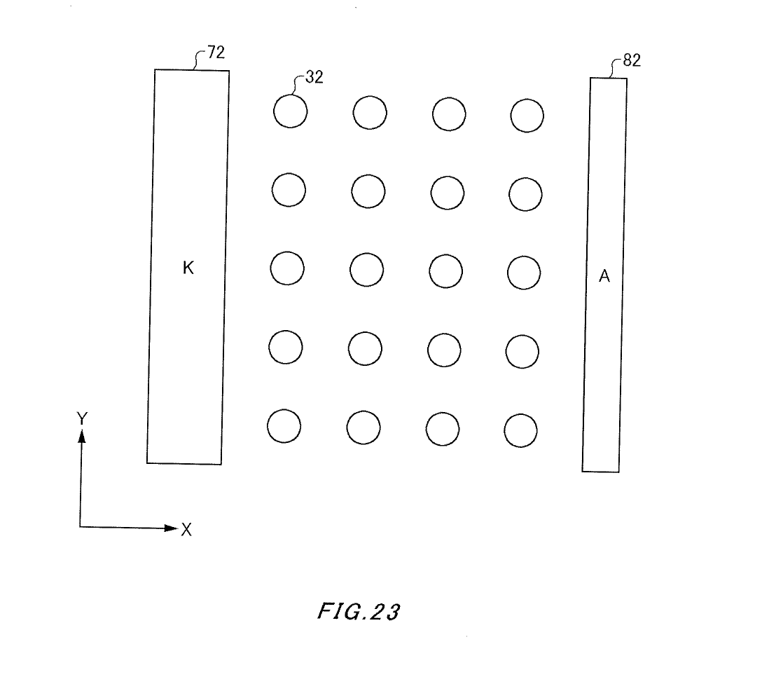

FIG. 23 is a top view illustrating the diode 200. The lower concentration regions 32 are arranged at even intervals and in a matrix on the surface of the electron transit layer 30. In other words, the lower concentration regions 32 are arranged at even intervals in the X axis direction and at even intervals in the Y axis direction on the surface of the electron transit layer 30. If the lower concentration regions 32 are arranged in the above-described manner, a large number of pn junctions can be formed in the region between the cathode electrode 72 and the anode electrode 82. Therefore, the concentration of the electrical field can be more reduced. Accordingly, the diode 200 can achieve improved withstand voltage.

Alternatively, the lower concentration regions 32 may be arranged at different intervals between in the X axis direction and in the Y axis direction. For example, the lower concentration regions 32 that are adjacent to each other in the Y axis direction may be out of alignment in the X axis direction and differently positioned in the X axis direction by half the interval at which the lower concentration regions 32 are arranged in the X axis direction. In this case, the interval between the lower concentration regions 32 in the Y axis direction is twice as large as the interval between the lower concentration regions 32 in the X axis direction. When the lower concentration regions 32 are arranged in this manner, the concentration of the electric field can be also reduced.

While the embodiments of the present invention have been described, the technical scope of the invention is not limited to the above described embodiments. It is apparent to persons skilled in the art that various alterations and improvements can be added to the above-described embodiments. It is also apparent from the scope of the claims that the embodiments added with such alterations or improvements can be included in the technical scope of the invention.

The operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

What is claimed is:

1. A nitride semiconductor device comprising:
a substrate;
an electron transit layer that is formed above the substrate;
an electron supply layer that is formed on the electron transit layer, the electron supply layer having a different band gap energy than the electron transit layer;
a drain electrode that is formed on the electron supply layer;
a gate electrode that controls an electric current flowing through the drain electrode; and
a source electrode that is formed on an opposite side of the drain electrode with the gate electrode being positioned between the source electrode and the drain electrode, wherein
a plurality of lower concentration regions are formed so as to be spaced away from each other on a surface of the electron transit layer between the gate electrode and the drain electrode, and
in the plurality of lower concentration regions, a concentration of a two-dimensional electron gas is lower than in other regions.

2. The nitride semiconductor device as set forth in claim 1, wherein
the plurality of lower concentration regions are formed by introducing an n-type dopant to a predetermined concentration using ion implantation.

3. The nitride semiconductor device as set forth in claim 2, wherein
the predetermined concentration is higher in one or more of the plurality of lower concentration regions that are closer to the drain electrode than in one or more of the plurality of lower concentration regions that are closer to the gate electrode.

4. The nitride semiconductor device as set forth in claim 2, wherein
the predetermined concentration is 1E16 cm⁻³ or higher.

5. The nitride semiconductor device as set forth in claim 1, wherein
the gate electrode is formed so as to penetrate through the electron supply layer.

6. The nitride semiconductor device as set forth in claim 1, wherein
the lower concentration regions are formed by applying laser.

7. The nitride semiconductor device as set forth in claim 1, wherein
the plurality of lower concentration regions are arranged at even intervals.

8. The nitride semiconductor device as set forth in claim 1, wherein
the plurality of lower concentration regions are arranged at even intervals and in a matrix on a surface of the electron transit layer.

9. The nitride semiconductor device as set forth in claim 2, wherein
the n-type dopant includes one of Si, Ge and O.

10. The nitride semiconductor device as set forth in claim 1, wherein
the electron transit layer contains GaN doped with a p-type dopant.

11. The nitride semiconductor device as set forth in claim 10, wherein
the p-type dopant includes one of Mg, Be, Zn and C.

12. The nitride semiconductor device as set forth in claim 1, wherein
the electron supply layer contains AlₓGa₁₋ₓN (0.01≦x≦0.4).

13. A nitride semiconductor device comprising:
a substrate;
an electron transit layer that is formed above the substrate;
an electron supply layer that is formed on the electron transit layer, the electron supply layer having a different band gap energy than the electron transit layer; and
a cathode electrode and an anode electrode that are formed on the electron supply layer, wherein
a plurality of lower concentration regions are formed so as to be spaced away from each other on a surface of the electron transit layer between the cathode electrode and the anode electrode and
in the plurality of lower concentration regions, a concentration of a two-dimensional electron gas is lower than in other regions.

14. A method of manufacturing a nitride semiconductor device, comprising:
forming an electron transit layer above a substrate;
forming, on the electron transit layer, an electron supply layer that has a different band gap energy than the electron transit layer;
forming a plurality of lower concentration regions so as to be spaced away from each other on a surface of the electron transit layer between a region in which a gate electrode is expected to be formed and a region in which a drain electrode is expected to be formed, the plurality of lower concentration regions having a lower concentration of a two-dimensional electron gas than other regions;
forming the drain electrode and a source electrode on the electron transit layer; and
forming the gate electrode that controls an electric current flowing though the drain electrode.

15. A method of manufacturing a nitride semiconductor device, comprising:
forming an electron transit layer above a substrate;
forming an electron supply layer on the electron transit layer, the electron supply layer having a different band gap energy than the electron transit layer;
forming a plurality of lower concentration regions so as to be spaced away from each other on a surface of the electron transit layer between a region in which a cathode electrode is expected to be formed and a region in which an anode electrode is expected to be formed, the plurality of lower concentration regions having a lower concentration of a two-dimensional electron gas than other regions;
forming the anode electrode on the electron supply layer; and
forming the cathode electrode on the electron supply layer.

16. The method as set forth in claim 14, wherein
the forming the plurality of lower concentration regions includes introducing an n-type dopant to a predetermined concentration using ion implantation.

17. The method as set forth in claim 15, wherein
the forming the plurality of lower concentration regions includes introducing an n-type dopant to a predetermined concentration using ion implantation.

18. The method as set forth in claim 14, wherein
the forming the plurality of lower concentration regions includes applying laser to form a crystal defect.

19. The method as set forth in claim 15, wherein
the forming the plurality of lower concentration regions includes applying laser to form a crystal defect.
